(19) United States
(12) Patent Application Publication
(10) Pub. No.: US 2012/0305282 A1
(43) Pub. Date: Dec. 6, 2012

(54) MOUNTING TUBE KIT

(76) Inventor: Grant E. Frazer, Capistrano Beach, CA (US)

(21) Appl. No.: 13/150,794

(22) Filed: Jun. 1, 2011

(51) Int. Cl. H05K 5/02; H05K 13/04

(52) U.S. Cl. 174/51; 29/592.1

(57) ABSTRACT

A kit or system of mounting tubes having various lengths that can be selected from to provide a single, one-piece device to fill the gap and provide the requisite support and stability between an electrical device or structural fixture and a mounting box (for example, junction box) is described. The mounting tubes are easy to install and can be used with any conventional components (for example, electrical devices, screws, fixtures). The mounting tubes can prevent wobbly fixtures or electrical devices, can reduce likelihood of electrical shock or other injury, and can reduce the likelihood of fires due to electrical failures caused by faulty installation. The mounting tubes can provide continuous grounding.

### FIELD

Embodiments of the invention generally relate to mounting of devices (for example, light fixtures, outlets) used in residential, commercial and industrial applications.

### BACKGROUND

When an electrical device, such as a light fixture or outlet, is to be mounted to a wall surface, there is often a gap or offset between the electrical device and an electrical box within the wall surface to which the electrical device is to be mounted. In some instances, a surface treatment (such as stucco, plaster, ceramic and stone facings, backsplashes) creates the gap. In some instances, the surface treatment or a poor mounting of the electrical box creates an uneven mounting surface, resulting in differing gap distances at different mounting locations of the electrical device. When installing electrical outlets to an electrical box within a wall, an opening in the wall can be so large that the mounting extensions or tabs of the outlet designed to hold the outlet against the wall cannot contact the wall at all or at least sufficiently to provide support, thereby preventing rigid and stable mounting of the outlet. The resultant gaps created by surface treatments and/or loose, non-rigid mounting caused by oversized holes can result in major safety and/or operational concerns, including code violations, electrical shock, fires, and operational failures.

### SUMMARY

In accordance with several embodiments, a mounting system for mounting electrical devices to junction boxes is provided. The mounting system can include a plurality of first mounting tubes having a first length, a plurality of second mounting tubes having a second length that is larger than the first length, and a plurality of third mounting tubes having a third length that is larger than the first length and the second length. In some embodiments, each of the first, second and third mounting tubes is a cylindrical, substantially non-compressible tube having an inner diameter of between 0.125 inch and 0.175 inch. In some embodiments, each of the first, second and third mounting tubes is formed of a conductive or substantially conductive material (for example, copper or other conductive metal). The mounting tubes may advantageously provide rigidity and allow for continuance of grounding between an electrical device and a junction box to which the electrical device is mounted.

In some embodiments, the mounting tubes have an outer diameter of approximately ¼ inch. In some embodiments, the mounting tubes have a length selected from the group consisting of: ¼ inch, ⅜ inch, ½ inch, ⅝ inch, ¾ inch, ⅞ inch, 1 inch, 1¼ inch, and 2 inches. In some embodiments, each of the mounting tubes is greater than ¼ inch. In some embodiments, each of the mounting tubes is completely hollow without any internal projections. In some embodiments, the mounting tubes are formed by cutting a section of long copper tubing into mounting tubes of different sizes.

In some embodiments, the mounting system further includes a plurality of first mounting screws having a size corresponding to the plurality of first mounting tubes, a plurality of second mounting screws having a size corresponding to the plurality of second mounting tubes, and a plurality of third mounting screws having a size corresponding to the plurality of third mounting tubes. In some embodiments, the mounting system includes a plurality of fourth mounting tubes having a length greater than the length of the plurality of third mounting tubes, a plurality of fifth mounting tubes having a length greater than the length of the plurality of fourth mounting tubes, a plurality of sixth mounting tubes having a length greater than the length of the plurality of fifth mounting tubes, a plurality of seventh mounting tubes having a length greater than the length of the plurality of sixth mounting tubes, and/or a plurality of eighth mounting tubes having a length greater than the length of the plurality of seventh mounting tubes.

In some embodiments, the mounting system comprises a kit. The kit can include a carrying case with compartments sized to receive the plurality of first mounting tubes, the plurality of second mounting tubes, and the plurality of third mounting tubes, respectively. The kit may also include a plurality of first mounting screws having a size corresponding to the plurality of first mounting tubes, a plurality of second mounting screws having a size corresponding to the plurality of second mounting tubes, and a plurality of third mounting screws having a size corresponding to the plurality of third mounting tubes. The kit can include higher, or larger, quantities of mounting tubes and/or screws having lengths that are more commonly used than mounting tubes and/or screws having less frequently used lengths.

In accordance with several embodiments, a method of mounting an electrical device to a junction box is provided. The method can include determining a first gap distance between a first mounting sleeve of a junction box for receiving a first screw and a first location on a plane of an exterior mounting surface to which an electrical device is to be mounted. The method can also include selecting a first mounting tube having a length equal or substantially equal to the first determined gap distance from a kit of mounting tubes having a plurality of lengths (for example, varying from 1/16 inch to 4 inches, from ¼ inch to 2 inches, from ¾ inch to 1¼ inches, from ⅜ inches to ⅞ inches).

The method can further include determining a second gap distance between a second mounting sleeve of a junction box for receiving a second screw and a second location on a plane of an exterior mounting surface to which an electrical device is to be mounted and selecting a second mounting tube having a length equal or substantially equal to the second determined gap distance from said kit of mounting tubes.

The method can also include inserting the first screw within the first mounting tube and inserting a distal end of the first screw through a slot of a mounting member of the electrical device. The method can further include inserting the distal end of the first screw through an opening of the first mounting sleeve and rotating the first screw until the first mounting tube substantially hinders further rotation of the first screw. The method can also include inserting the second screw within the second mounting tube and inserting a distal end of the second screw through a second slot of the mounting member of the electrical device. The method can further include inserting the distal end of the second screw through an opening of the second mounting sleeve and rotating the second screw until the second mounting tube substantially hinders further rotation of the second screw.

In some embodiments, the first mounting tube and the second mounting tube comprise substantially non-compressible metallic tubes. In some embodiments, the first mounting tube and/or the second mounting tube are configured to provide continuous ground conductivity from the electrical device to the junction box. In some embodiments, the first mounting tube and the second mounting tube have the same length. In other embodiments, the first mounting tube and the second mounting tube have different lengths (for example, if the mounting surface is uneven or non-level, resulting in different sized gaps). In some embodiments, the first gap distance and the second gap distance include a width of an exterior wall surface treatment. In some embodiments, the method further includes adjusting a length of the first and/or second mounting tubes based on the measured gap distances.

For purposes of this summary, certain aspects, advantages, and novel features of the invention are described herein. It is to be understood that not necessarily all such advantages may be achieved in accordance with any particular embodiment of the invention. Thus, for example, those skilled in the art will recognize that the invention may be embodied or carried out in a manner that achieves one advantage or group of advantages as taught herein without necessarily achieving other advantages as may be taught or suggested herein.

### BRIEF DESCRIPTION OF THE DRAWINGS

Throughout the drawings, reference numbers are re-used to indicate correspondence between referenced elements. The drawings are provided to illustrate embodiments of the inventions described herein and not to limit the scope thereof

FIG. 1A is an exploded view illustrating an embodiment of the mounting tubes and component parts of a mounting assembly in one intended environment of use. FIG. 1A illustrates the mounting tubes being used to aid in mounting an exterior light fixture to a junction box within an exterior wall.

FIG. 1B is a partial cross-sectional side view illustrating the assembly of FIG. 1A once all of the component parts have been installed.

FIG. 2A is an exploded view illustrating an embodiment of the mounting tubes and component parts of a mounting assembly in another intended environment of use. FIG. 2A illustrates the mounting tubes being used to aid in mounting an outlet to an electrical box within an interior wall.

FIG. 2B is a partial cross-sectional side view illustrating the assembly of FIG. 2A once all of the component parts have been installed.

FIGS. 3A-3C illustrate a perspective, side and top view of an embodiment of a mounting tube.

FIGS. 4 and 5 illustrate embodiments of kits of mounting tubes having varying lengths.

FIG. 6 illustrates an embodiment of a kit of mounting tubes and corresponding screws of varying sizes.

### DETAILED DESCRIPTION

### I. Introduction

Embodiments of the invention are designed to address the problem of mounting light fixture bars and/or electrical devices to existing mounting boxes (for example, electrical junction boxes, receptacle boxes or gang boxes of any configuration or size) attached to a support member (for example, a 2×4 stud) behind a boundary structure (for example, wall, ceiling, floor) in which substantially large (for example, non-standard or unexpected) gaps exist between mounting features of the light fixture bar and/or electrical device and corresponding mounting features of the mounting boxes. Typically, mounting boxes are installed such that the mounting features of the mounting boxes are flush with, substantially flush with, or slightly recessed from the exterior boundary surface (for example, wall, ceiling, floor). However, exterior surface treatments or construction additions can be applied over the existing boundary surface (for example, wall surface), thereby resulting in substantial gaps or offset distances between the mounting features of the mounting boxes and corresponding mounting features of the device or structure to be mounted. The substantial gaps or offset distances can increase the difficulty or complexity of installing electrical, decorative or other devices to a mounting box behind a wall and/or can result in major safety and/or operational concerns, including code violations, electrical shock, fires, and operational failures

In some instances, a wall surface surrounding a mounting box has become weak or a hole in the wall has been sized so large such that an electrical device cannot be mounted flush with the wall surface in a rigid manner because the installer cannot rely on the strength of the mounting box or the wall structure to provide rigidity. Instead, the electrical device (for example, a convenience outlet) is typically mounted in a loose, wobbly, non-rigid and/or unstable manner that can lead to hazardous safety issues (for example, fires, electrical shock) or failed or intermittent operation of the electrical device. For example, the lack of stability and rigidity can result in intermittent operational failure due to lack of a continuous grounding.

In still other instances, a mounting box can be mounted to a support member or framing structure in a less than precise manner such that the mounting box is offset at an angle with respect to the wall surface or the surface treatment covering the mounting box can provide an uneven surface, thereby resulting in gaps of different length at different mounting locations.

A conventional prior art solution to the “gap” problem is to stack several washers or plastic square spacers with central holes together on a mounting screw between the mounting box and the electrical device until the total gap to the finished wall is “filled.” The stacking of multiple spacers or washers can compromise structural rigidity and stability due to the presence of multiple non-integral or non-unitary component parts. Another drawback to existing solutions involving stacking of multiple component parts (especially parts made of compressible material) is that the total gap to be filled will change when torquing down mounting screws or other fasteners. In addition, rigidity and stability may decrease over time as some of the component parts (for example, spacers or washers) degrade with use or over time.

This disclosure describes a kit or system of mounting tubes having various lengths that can be selected from to provide a single, one-piece device to fill the gap and provide the requisite support and stability between the electrical device or structural fixture and the mounting box (for example, junction box). The mounting tubes are easy to install and can be used with any conventional components (for example, electrical devices, screws, fixtures). The mounting tubes can prevent wobbly fixtures or electrical devices, can reduce likelihood of electrical shock or other injury, and can reduce the likelihood of fires due to electrical failures caused by faulty installation. The mounting tubes are not adjustable or compressible during or after installation, thereby filling and maintaining the gap distance in a permanent fashion. For example, a tradesman can be assured that the mounting tube selected based on a measured gap distance will provide the correct solution because there will be no compression during installation, unlike prior stackable and compressible solution options.

Advantageously, in certain embodiments, the mounting tubes are formed of non-compressible or substantially non-compressible conductive material (for example, copper) and form a solid, rigid connection between metallic materials of the electrical device or structural fixture and metallic junction boxes (for example, galvanized junction box), having continuous metallic shielding (for example, rigid or flex conduit), thereby providing a continuance of grounding. In some embodiments, the mounting tubes comprise non-conductive but non-compressible or substantially non-compressible material. Advantageously, in certain embodiments, the mounting tubes described herein provide increased and permanent stability as compared with stacked devices or spacers made of softer materials such as plastic or other compressible materials or materials that can degrade over time. The degradation of the plastic or compressible materials can also result in loss of grounding over time. Typically, cover plates are left loose to achieve a specific distance and the installation relies on the plate as a means of tightening. In some implementations, the mounting tubes described herein can prevent or reduce the likelihood of breakage of switch or receptacle plates that are made of brittle plastic due to over tightening of a screw or other fastening member (for example, screwing the screw in too far).

In some embodiments, the kit of mounting tubes of varying lengths advantageously allows different sized tubes to be selected for different mounting locations (for example, opposite sides of the same electrical, receptacle or junction box), which may have gaps of different lengths due to an uneven (for example, non-uniform or non-level) mounting surface or a misaligned (non-level) junction box, with each mounting tube providing a single one-piece gap-filling device (for example, shim or spacer). In some implementations, a plurality of mounting tubes of varying sizes can be provided in a convenient carrying case (with or without screws of corresponding lengths). As a result, in certain embodiments, the kit provides greater flexibility to users (for example, tradesmen) requiring rigid, conductive, monolithic devices of varying lengths designed to fill gaps of varying distances while providing stability and a continuous grounding option in accordance with established standards and required electrical codes. The kit of mounting tubes can provide a less time-consuming solution than the conventional crude solutions of stacking washers or shims or wrapping wire around the screws or other fastening members.

As used herein, the term “wall,” in addition to having its ordinary meaning, is used interchangeably to refer to any structural boundary (for example, a substantially vertical wall, a ceiling (whether substantially horizontal, vaulted, or slanted), a floor, or the like).

### II. Example Environments of Intended Use

A. Exterior Junction Boxes

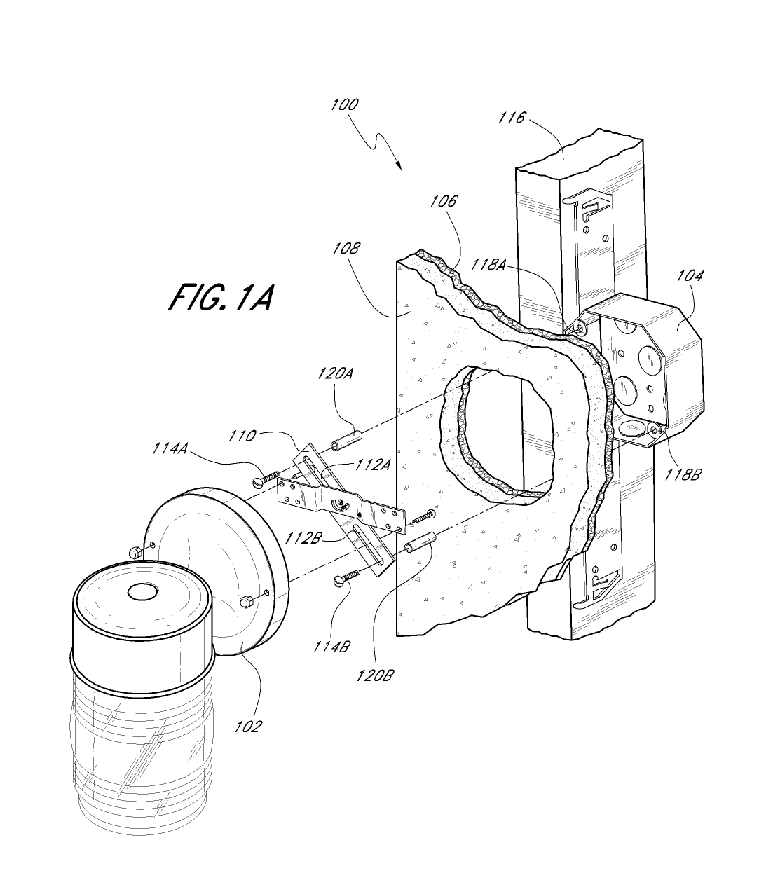

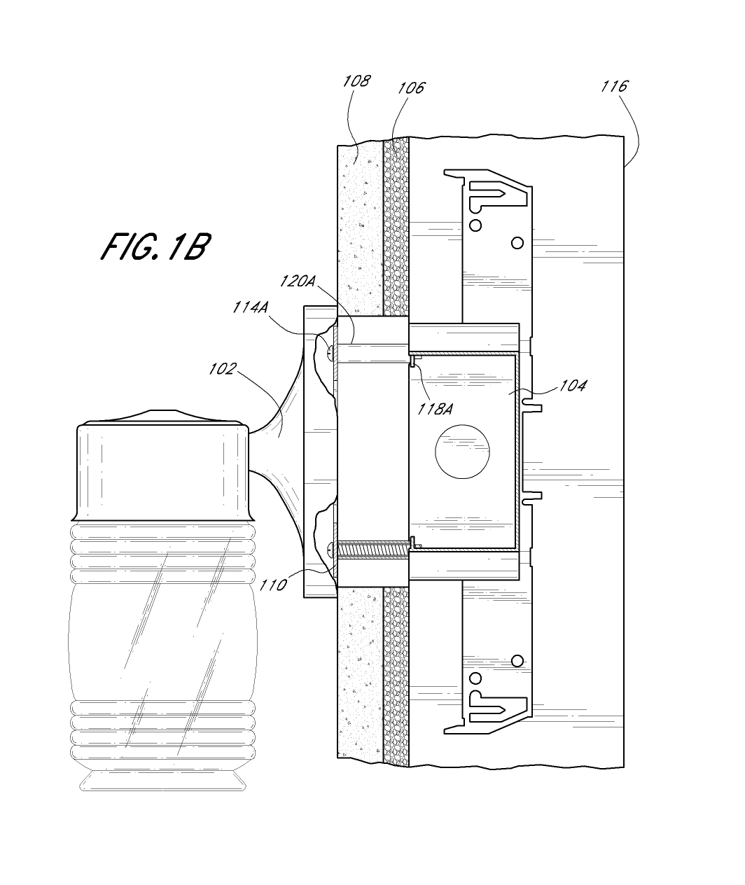

FIGS. 1A and 1B illustrate an embodiment of an environment 100 in which the mounting tubes disclosed herein can be used. The environment 100 illustrated in FIGS. 1A and 1B involves mounting of an outdoor lighting fixture 102 to a junction box 104 behind an exterior wall 106 having an exterior surface treatment 108 (for example, stucco). The exterior surface treatment 108 covering the exterior wall 106 creates a substantial gap between the junction box 104 and the exposed surface of the wall. FIG. 1A illustrates an exploded view of an example assembly and FIG. 1B illustrates a partial cross-sectional side view post-installation.

The outdoor lighting fixture 102 can be any conventional wall-mounted lighting fixture of any size or shape (e,g., sconce, pendant, lantern, lamp, chandelier). The outdoor lighting fixture 102 can be substituted with any other electrical device (for example, a switch, a timer, an outlet, a Ground Fault Circuit Interrupter (GFCI) outlet). As shown, the outdoor lighting fixture 102 can be provided with an installation bracket 110. The installation bracket 110 can include two slots 112 sized and shaped to receive fastening members 114 (for example, mounting screws).

The junction box 104 can comprise an octagon box, a round box, a square box, a rectangular box, or any other shape. The junction box 104 can be metallic (for example, galvanized steel) or plastic. The junction box 104 is typically secured (for example, anchored) to a framing or structural support member 116 (for example, a 2×4 stud, metal beam, cement structure, floor, ceiling) that can provide stable fixation of the junction box 104. The junction box 104 includes mounting members 118 (for example, mounting sleeves or tabs) having openings or apertures configured to receive the fastening members 114. The openings or apertures may be threaded.

The exterior surface treatment 108 can comprise any surface coating material or construction addition (for example, stucco, plaster, brick, stone, cement). The exterior surface treatment 108 can result in an uneven mounting surface for the outdoor lighting fixture 102 such that offset distances or gaps between the mounting surface and mounting features at different mounting locations of the outdoor lighting fixture can have different gap or offset distance measurements.

As illustrated, a mounting tube 120 can be placed over each of the fastening members 114 (for example, mounting screws) that have been inserted through the slots 112 of the installation bracket 110. The fastening members 114 are inserted through corresponding openings 120 of the mounting members 118 of the junction box 104 and tightened until the mounting tube 120 substantially prevents further tightening (for example, without excessive force or torque). As shown in FIG. 1B, the mounting tubes 120 can provide continuous conductivity (for example, grounding) between the installation bracket 110 and the junction box 104 (each of which can be formed of conductive material such as metal). In some instances, the fastening members 114 (which may be metallic screws) alone without the mounting tubes 120 cannot provide stable grounding because the loose connection caused by the gaps allows for shifting of the shaft of the fastening members 114 within the slots 112 of the installation bracket 110, which can temporarily or intermittently interrupt the grounding connection.

In some embodiments, the manner of using the mounting tubes 120 starts with determining gap or offset distances between an exposed mounting surface (for example, the exposed exterior surface of surface treatment 108) and one or more mounting members (for example, mounting sleeves 118) of the junction box 104. The gap or offset distances for the junction box 104 may be the same or substantially the same or may be substantially different (for example, depending on whether the exposed surface presents an even or uneven (non-level or non-uniform) surface and/or depending on the alignment or positioning of the junction box 104). In some embodiments, the gap or offset distances are determined using a measuring tool (such as a ruler or measuring tape). In some embodiments, mounting tubes of different sizes can be held up to the gap until an appropriately-sized tube is identified or determined.

After determining the gap or offset distances, mounting tubes 120 (one for each mounting member 118 on opposite sides of the junction box 104) having a length equal to, substantially equal to, slightly less than, or slightly greater than, the determined gap distances (which may be the same or different) are selected from a kit of mounting tubes 120 (for example, kits 400, 500). In some embodiments, two mounting tubes are selected to be stacked to equal a determined gap distance. In some embodiments, a mounting tube can be trimmed or cut (for example, by a conventional pipe or tube cutting tool) to obtain a determined gap distance.

In some embodiments, upon selection of appropriately-sized mounting tubes 120, a first fastening member 114A (for example, mounting screw) is inserted through a first slot 112A of the installation bracket 110 and then a first mounting tube 120A is placed over the first fastening member 114A. A distal end of the first fastening member 114A is then inserted through an opening of a first mounting member 118A (for example, mounting sleeve or tab) of the junction box 104. The first fastening member 114A is then tightened (for example, threaded, rotated, inserted) until the first mounting tube 120A substantially prevents or hinders further tightening without excessive force or torque, thereby ensuring a rigid and stable support and continuous grounding capability (if all component parts are conductive) are provided. The process described with respect to the first mounting tube 120A is then repeated for the second mounting tube 120B. In some embodiments, the first mounting tube 120A and the second mounting tube 120B are installed in reverse order or simultaneously. After the installation bracket 110 has been secured using the mounting tubes 120, the light fixture 102 can be attached to the installation bracket 110 using fastening members 122.

B. Interior Electrical Boxes

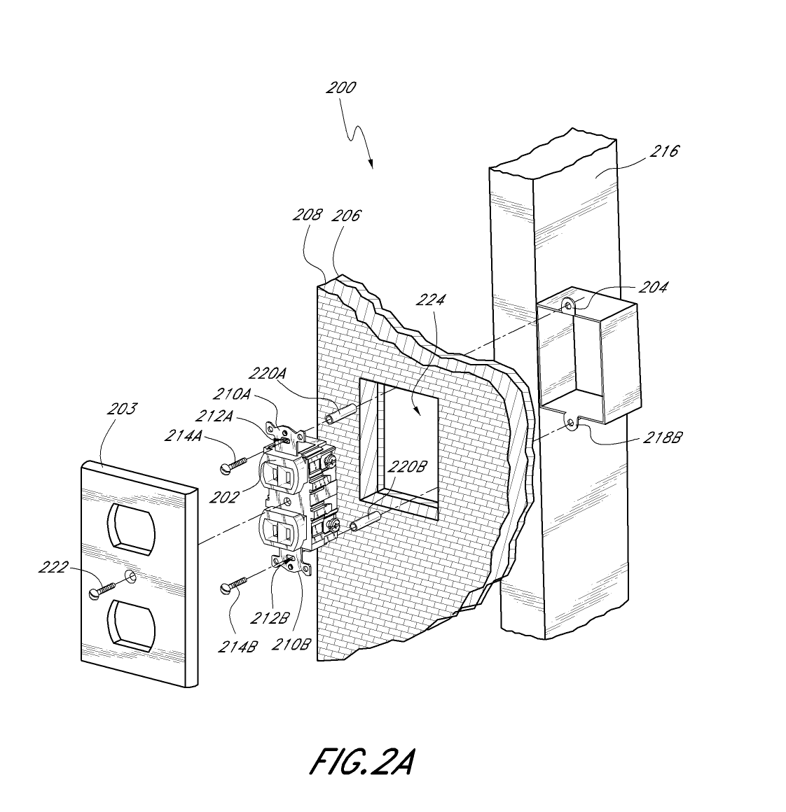

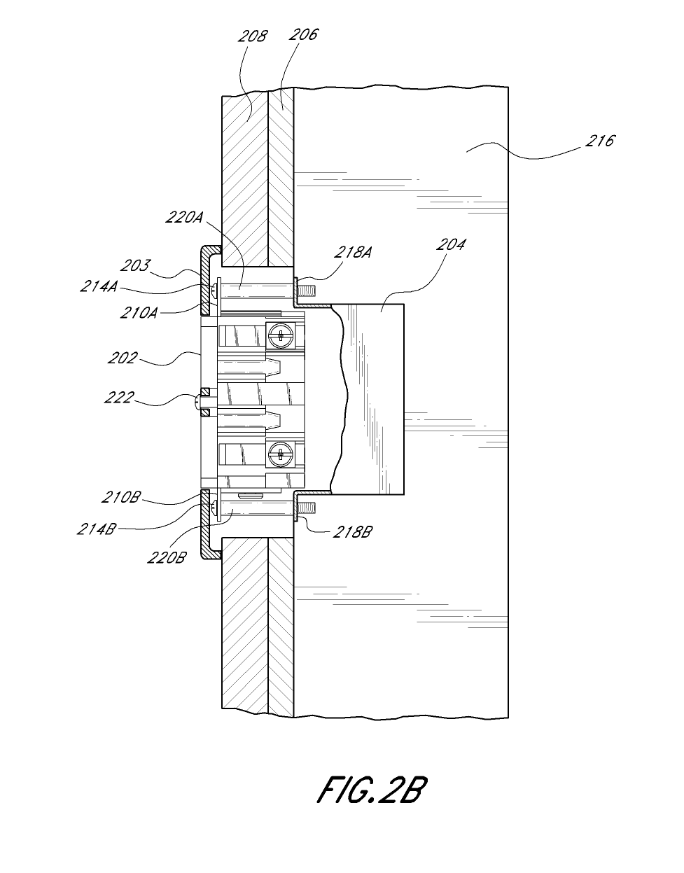

FIGS. 2A and 2B illustrate an alternative embodiment of an environment 200 in which the mounting tubes disclosed herein can be used. The environment 200 illustrated in FIGS. 2A and 2B involves mounting of an electrical fixture 202 (for example, switch, outlet, receptacle) to an electrical box 204 (for example, outlet box) behind a wall 206. The wall 206 is covered with a surface treatment 208 (for example, cement board and tile, ceramic or stone facings, backsplashes, wainscoting, paneling, mirroring, brick, cabinets, built-in entertainment unit). The surface treatment 208 covering the wall 206 can create a substantial gap between the electrical box 204 and the exposed surface of the wall, which can present difficulty in mounting the electrical device flush or substantially flush with the exposed surface in a rigid and stable fashion. FIG. 2A illustrates an exploded view of an example assembly and FIG. 2B illustrates a partial cross-sectional side view post-installation.

Although illustrated as a conventional outlet, the electrical fixture 202 can be a conventional light switch, a dimmer switch, a button switch, or any other type of switch, a receptacle cover or plate, a GFCI outlet, a phone jack, a cable connector (for example, TV or Internet), a surface-mount light fixture, a sconce, a switch timer, and/or the like. The illustrated electrical fixture 202 comprises an outlet that is covered by a cover or plate 203. The illustrated electrical fixture 202 further includes mounting tabs 210 having slots 212 sized and shaped to receive fastening members 214 (for example, mounting screws). The mounting tabs 210 are ideally secured against an exposed surface of the wall 206 or an overlying surface treatment when the fastening members are tightened. However, in many installations, an opening 224 in the wall 106 is irregular, oversized, or improperly positioned such that one or both of the mounting tabs 210 do not securely contact the wall 106 or an overlying surface treatment. In such installations without mounting tubes 220, the electrical fixture 202 typically remains loose or is affixed at a recessed location. Therefore, the mounting is not rigid or stable and is susceptible to operational failures, damage, fires, shock, pull-out, and/or the like.

The electrical box 204 can comprise an outlet box, a round box, a square box, a rectangular box, a gang box configured to house multiple outlets, switches, or other electrical fixtures, or any other receptacle or mounting box. The electrical box 204 can be metallic (for example, galvanized steel, aluminum) or plastic. The electrical box 204 is typically secured to a framing or structural support member 216 (for example, a 2×4 stud, metal beam, cement structure, floor, ceiling) that can provide stable fixation of the electrical box 204. The electrical box 204 includes mounting sleeves 218 having openings or apertures configured to receive the fastening members 214 (for example, mounting screws). The openings or apertures may be threaded.

In accordance with some embodiments, the mounting tubes 220 can be inserted over the fastening members 214 (for example, mounting screws) between the mounting tabs 210 and the mounting sleeves 218 after insertion of the fastening members through the slots 212 of the mounting tabs 210. The fastening members 214 are inserted through corresponding openings 220 of the mounting sleeves 218 of the electrical box 204 and tightened until the mounting tube 220 substantially prevents further tightening (for example, without excessive force or torque). As shown in FIG. 2B, the mounting tubes 220 can provide continuous conductivity (for example, grounding) between the mounting tabs 210 and the electrical box 204 (each of which can be formed of conductive material such as metal). In some instances, the fastening members 214 (which may be metallic screws) alone without the mounting tubes 220 cannot provide stable grounding because the loose connection caused by the gaps allows for shifting of the shaft of the fastening members 214 within the slots 212 of the mounting tabs 210, which can temporarily or intermittently interrupt the grounding connection.

In certain embodiments, the mounting tubes 220 advantageously prevent against over tightening of the fastening members such that the mounting tabs 210 of the outlet 202 bend inward due to the fact that the mounting tab 210 of the outlet 202 is brought too close to the corresponding mounting sleeve 218 of the electrical box 204 (for example, the separation distance between the mounting tab 210 and the corresponding mounting sleeve 218 is minimized past a desired, ideal, or required distance), which can break the cover or face plate 203. In some embodiments, the mounting tubes 220 prevent stripping.

In some embodiments, the manner of using the mounting tubes 220 starts with determining gap distances between an exposed mounting surface and one or more mounting locations (for example, mounting sleeves 218) of the electrical box 204. The gap distances may be the same or substantially the same or may be substantially different (for example, depending on whether the exposed surface presents an even or uneven surface and/or depending on the alignment or positioning of the electrical box 204). In some embodiments, the gap distances are determined using a measuring tool (such as a ruler or measuring tape). In some embodiments, mounting tubes can be held up to the gap until an appropriately-sized tube is identified or determined.

After determining the gap distances, mounting tubes 220 (one for each mounting sleeve 218 on opposite sides of the electrical box 204) having a length equal or substantially equal to the determined gap distances (which may be the same or different) are selected from a kit of mounting tubes 220 (for example, kits 400, 500). In some embodiments, two mounting tubes are selected to be stacked to equal a determined gap or offset distance. In some embodiments, a mounting tube can be trimmed or cut (for example, by a conventional pipe or tube cutting tool) to obtain a determined gap or offset distance.

In some embodiments, upon selection of appropriately-sized mounting tubes 220, a first fastening member 214A (for example, mounting screw) is inserted through a first slot 112A of the mounting tab 210A and then a first mounting tube 220A is placed over the first fastening member 214A. A distal end of the first fastening member 214A is then inserted through an opening of a first mounting sleeve 218A of the electrical box 204. The first fastening member 214A is then tightened (for example, threaded, rotated, inserted) until the first mounting tube 220A substantially prevents or hinders further tightening of the first fastening member 214A without excessive force or torque, thereby ensuring a rigid and stable support and continuous grounding capability (if all component parts are conductive) are provided. The process described with respect to the first mounting tube 220A is then repeated for the second mounting tube 220B. In some embodiments, the first mounting tube 220A and the second mounting tube 220B are installed in reverse order or simultaneously. After the mounting tabs 210 have been secured using the mounting tubes 220, the cover or face plate 203 can be attached to the electrical device 202 using a fastening member 222. III. Mounting Tubes

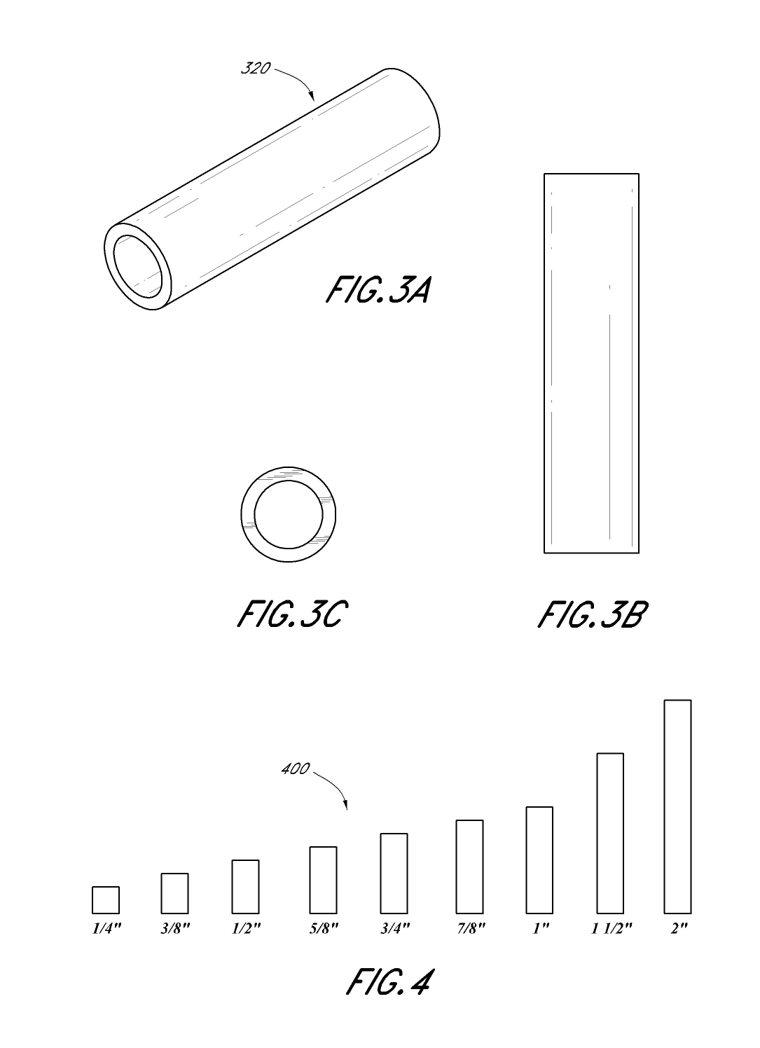

FIGS. 3A-3C illustrate a perspective view, a side view, and a top view, respectively of an embodiment of a mounting tube 320. In some embodiments, the mounting tube 320 and other mounting tubes described herein comprise a rigid, conductive material. In some embodiments, the mounting tubes comprise metal (for example, copper, aluminum, steel, stainless steel, galvanized steel, or other metal). In some embodiments, the mounting tubes are conductive; however, in other embodiments, the mounting tubes are non-conductive. In some embodiments, the mounting tubes are formed by cutting off a section of long tubing. In one embodiment, the mounting tubes described herein are formed from cutting copper refrigeration tubing into segments. In other embodiments, the mounting tubes are formed from rigid plastic or other polymer (for example, nylon or acrylonitrile-butadiene-styrene).

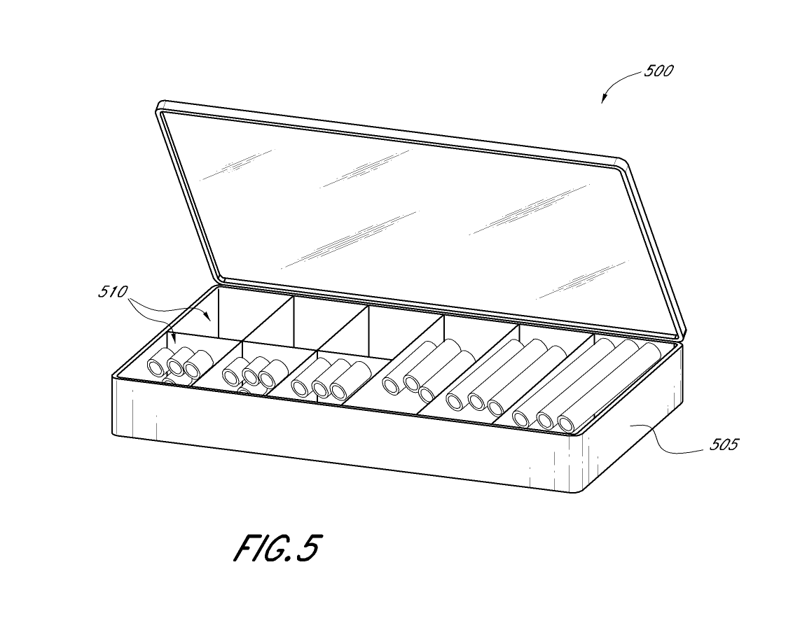

The mounting tubes described herein (for example, mounting tube 320) can be sized and shaped to receive 6-gauge or 8-gauge fastening members (for example, #6 screws, 6-32 screws, #8 screws, and/or 8-32 screws). However, in some embodiments, the mounting tubes can be sized to receive fastening members having a larger or smaller gauge as desired and/or required. In some embodiments, the mounting tubes comprise hollow cylinders or sleeves without any structural features (for example, projections) within the central lumen of the mounting tubes. In some embodiments, the mounting tubes do not have a notched cutout or an opening extending along the length of the tube, thereby increasing the non-compressive feature and structural rigidity of the mounting tube. In some embodiments, the internal diameter of the mounting tubes is between about 0.060″ and about 0.400″, between about 0.100″ and about 0.200″, between about 0.125″ and about 0.175″, about 0.140″, less than 0.060″, greater than 0.400″, or overlapping ranges thereof. The outer diameter of the mounting tubes can be between about 0.080″ and about 0.600″, between about 0.125″ and about 0.325″, between about 0.200″ and about 0.300″, about 0.250″, less than 0.080″, greater than 0.600″, or overlapping ranges thereof. As will be described in further detail with reference to FIGS. 4 and 5, the mounting tubes can range in length from about 1/16″ to about 4″, from about ¼″ to about 2″, from about ⅛″ to about 2½″, or overlapping ranges thereof, as desired and/or as required by code requirements. The mounting tubes function as shims or spacers in accordance with some embodiments.

### IV. Kits

With reference to FIG. 4, a kit 400 of mounting tubes may advantageously be provided in accordance with several embodiments of the invention. The kit 400 may advantageously include mounting tubes of varying lengths. In some embodiments, the kit 400 may advantageously include mounting tubes having varying lengths and/or varying diameters.

In some embodiments, the kit 400 may advantageously include mounting tubes ranging from about 1/16″ to about 4″, from about ⅛″ to about 3″, from about ¼″ to about 2″, less than 1/16″, greater than 4″, or overlapping ranges thereof. The kit 400 may include mounting tubes of eight different lengths, ranging from ¼″ to 2″ (¼″, ⅜″, ½″, ⅝″, ¾″, 1″, 1¼″, 2″). In one embodiment, (as shown in FIG. 4), the kit 400 may include mounting tubes of nine different lengths, ranging from ¼″ to 2″ (¼″, ⅜″, ½″, ⅝″, ¾″, ⅞″, 1″, 1¼″, 2″). In other embodiments, the kit 400 includes mounting tubes in ⅛″ increments from ⅛″ to 2″ (for example, 16 different sizes) or from ¼″ to 2″ (for example, 15 different sizes). In still other embodiments, the kit 400 comprises any other combination of sizes of mounting tubes within the range from about 1/16″ to about 4″ in various increments (for example, 1/16″ increments, ⅛″ increments, ¼″ increments ½″ increments). The mounting tubes can be manufactured in bulk by cutting appropriately-sized sections of a long (for example, 10-foot, 100-foot, 1000-foot) length of tubing. In some embodiments, mounting tubes having lengths that are determined to be more commonly used can be provided in a greater quantity than mounting tubes having lengths that are less likely to be used.

In some embodiments, different kits of mounting tubes may advantageously be provided for various jobs or purposes. For example, one kit of mounting tubes may be adapted for mounting outdoor lighting fixtures. An average range of gap or offset distances for mounting outdoor lighting fixtures can be determined and then a kit of mounting tubes having lengths within that range can be provided. For example, an appropriate overall range can be determined and then mounting tubes having lengths of varying percentages within that range can be provided. As one example, a range of ¼ inch to 2 inches can be determined as the overall range for mounting outdoor lighting fixtures so that 1¾ inches corresponds to the 100% length and then mounting tubes having lengths corresponding to varying percentages within that 100% can be provided (for example, 10%, 20%, 30%, 40%, 50%, 60%, 70%,80%, 90%, 100% or other percentages within these percentages). A kit for mounting outlets on an interior wall may have a different overall range and a different set of mounting tubes than those provided in the kit for mounting outdoor lighting fixtures. For example, the kit for mounting outlets on an interior wall may have a different overall range (for example, a smaller overall range) or the kit may have different quantities of the various mounting tube sizes than those provided in a kit for mounting devices on an exterior wall.

Mounting tubes having frequently-used lengths can be provided in greater quantity than mounting tubes of other lengths as described above. In some embodiments, the kits include a higher quantity of mounting tubes having lengths in the middle of the range than mounting tubes having lengths in the lower or upper range due to frequency of use. As one example of a kit having different quantities of mounting tubes of different lengths based on frequency of use, a kit designed for exterior light fixture mountings may advantageously include a larger quantity of mounting tubes having lengths of ¾″, ⅞″, 1″, and 1¼″ than mounting tubes of other lengths. As another example of a kit having different quantities of mounting tubes of different lengths based on frequency of use, a kit for mounting outlets on an interior wall surface may advantageously include a larger quantity of mounting tubes having lengths of ⅜″, ½″, ⅝″, ¾″, ⅞″ and/or 1″ than mounting tubes of other lengths, which may be less commonly used. In one embodiment, a larger quantity of mounting tubes having lengths in the higher ranges are provided in kits designed for applications in which medium to large gaps exist (such as extending outlets in the backings of cabinets or built-ins such as entertainment centers or book cabinets). In one embodiment, a larger quantity of mounting tubes in the lower ranges are provided in kits designed for small to medium gaps (for example, mounting on porcelain or ceramic tiles used for kitchen counter backsplashes or light sconces mounted on mirrored surfaces). In some embodiments, the kits are standardized and adapted to provide mounting tubes for any mounting situation or application (whether for interior applications or exterior applications).

With reference to FIG. 5, a kit 500 of mounting tubes can include a plurality of mounting tubes of varying lengths. The kit 500 can be conveniently assembled in a carrying case or tray 505. The carrying case or tray 505 can be divided into compartments 510 of different sizes designed to accommodate mounting tubes of different sizes. The carrying case 505 can include size labels, a legend, color coding and/or other indicia for convenient identification. In some embodiments, the kit 500 can include #6 and/or #8 screws (or screws having other gauges) having varying lengths corresponding to the lengths of the mounting tubes.

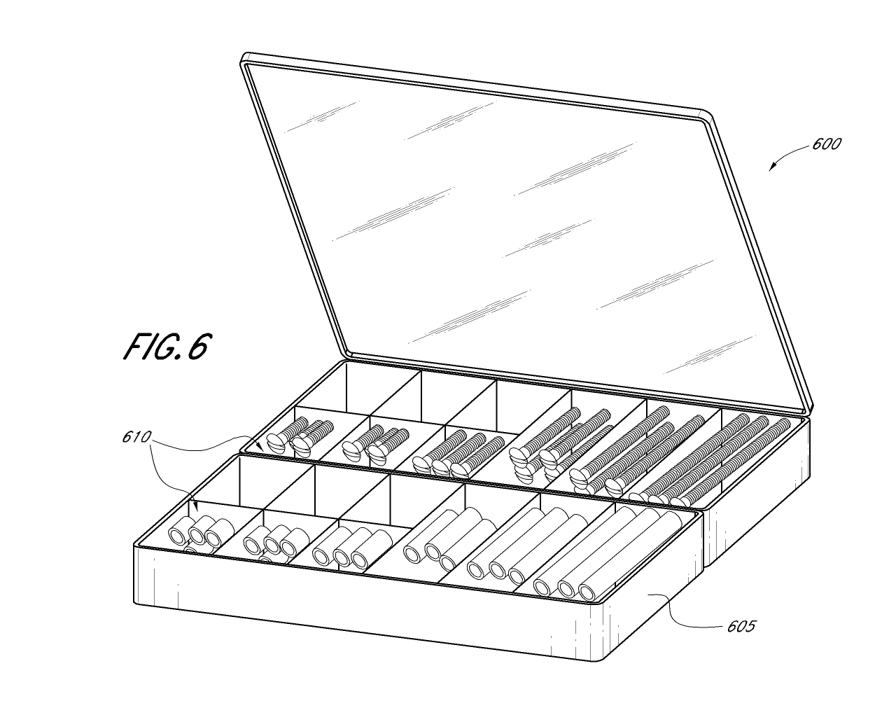

In one embodiment, a kit of mounting tubes can be provided as a companion case, an insert, or an attachment to a kit of screws, bolts or other fasteners of corresponding sizes. For example, a kit of mounting tubes can be conveniently attached to or made a part of a standard carrying case or kit of screws, bolts or other fasteners of various sizes typically carried by a handyman or tradesman. FIG. 6 illustrates a schematic representation of a kit 600 including a carrying case 605 having mounting tubes and corresponding screws of varying lengths in compartments 610 of varying sizes. Other configurations, arrangements, quantities, etc. than those illustrated can be used without departing from the spirit and/or scope of the disclosure. In some embodiments, mounting tubes and screws, bolts, or other fasteners of corresponding lengths are provided together in a single compartment or in neighboring compartments of the same carrying case. In some embodiments, mounting tubes and screws, bolts, or other fasteners of corresponding lengths are provided in compartments of separate carrying cases or in compartments of separate components of a single carrying case having an attachment or insert. In some embodiments, the corresponding screws, bolts, or fasteners are slightly larger than (for example, up to 5 mm larger than, about 1 to 3 mm larger than, about 1 to 2 mm larger than, up to 1 cm larger than, greater than 1 cm larger than, up to ½ inch larger than, about ½ inch larger than) the mounting tubes. Mounting tubes and corresponding fasteners having frequently-used lengths can be provided in greater quantity than mounting tubes and corresponding fasteners of other lengths as described above.

The kits 400, 500 and 600 can advantageously provide flexibility and convenience to a user (for example, a tradesman) to allow for custom fitting when there are gaps of different sizes or non-standard sizes for a particular fixture or electrical device to be mounted or on a large project requiring installation of several fixtures or electrical devices. Rather than simply stacking washers or spacers until a gap is filled, the user can measure the gap or offset distance and then select the appropriately-sized monolithic mounting tube having the measured length or a substantially similar length. In some embodiments, the kits can include a cutting tool (such as a conventional pipe or tubing cutter) to allow for further customization based on determined gap or offset sizes. In some embodiments, two mounting tubes of varying sizes can be stacked on top of each other as desired and/or required while still maintaining stability and conductivity. The kits 400, 500, 600 of mounting tubes of varying lengths advantageously allow for selection of mounting tubes of different lengths for a single fixture that may have different gap or offset distances at different mounting locations. In some embodiments, the kits 400, 500, 600 advantageously allow a user to select an appropriately-sized monolithic mounting tube for any situation or application.

### V. Terminology

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced item.

Although the embodiments are illustrated and substantially described herein with reference to a wall surface, the mounting tubes can be used to mount electrical devices or fixtures to or within ceiling surfaces or floor surfaces. Although mounting tubes are described herein, non-tubular or non-cylindrical spacers or shims may be substituted without departing from the spirit and/or scope of the disclosure. Although electrical devices are described as being mounted herein for the most part, non-electrical devices can be mounted using the mounting tubes described herein.

Although particular embodiments have been described, numerous variations and alterations to the disclosed embodiments will be apparent form the foregoing disclosure. For examples, any of the features of the described embodiments can be combined in variations different from or in addition to those specifically described and/or illustrated.

What is claimed is:

1. A mounting system for mounting electrical devices to junction boxes, the mounting system comprising:
a plurality of first mounting tubes having a first length;
a plurality of second mounting tubes having a second length that is larger than said first length;
a plurality of third mounting tubes having a third length that is larger than said first length and said second length,
wherein each of said plurality of first, second and third mounting tubes is a cylindrical, substantially non-compressible tube having an inner diameter of between 0.125 inch and 0.175 inch, and
wherein each of said plurality of first, second and third mounting tubes is formed of copper, thereby providing rigidity and allowing for continuance of grounding between an electrical device and a junction box to which the electrical device is to be mounted.

2. The mounting system of claim 1, wherein said mounting tubes have an outer diameter of approximately ¼ inch.

3. The mounting system of claim 1, wherein said mounting tubes have a length selected from the group consisting of: ¼ inch, ⅜ inch, ½ inch, ⅝ inch, ¾ inch, 1 inch, 1¼ inch, and 2 inches.

4. The mounting system of claim 1, wherein each of said mounting tubes is greater than ¼ inch.

5. The mounting system of claim 1, wherein each of said mounting tubes is completely hollow without any internal projections.

6. The mounting system of claim 1, wherein each of said mounting tubes is formed by cutting a section of copper tubing into mounting tubes of different sizes.

7. The mounting system of claim 1, further comprising a plurality of first mounting screws having a size corresponding to the plurality of first mounting tubes, a plurality of second mounting screws having a size corresponding to the plurality of second mounting tubes, and a plurality of third mounting screws having a size corresponding to the plurality of third mounting tubes.

8. The mounting system of claim 1, further comprising:
a plurality of fourth mounting tubes having a length greater than the length of the plurality of third mounting tubes;
a plurality of fifth mounting tubes having a length greater than the length of the plurality of fourth mounting tubes;
a plurality of sixth mounting tubes having a length greater than the length of the plurality of fifth mounting tubes;
a plurality of seventh mounting tubes having a length greater than the length of the plurality of sixth mounting tubes; and
a plurality of eighth mounting tubes having a length greater than the length of the plurality of seventh mounting tubes.

9. A kit of mounting tubes for mounting electrical devices to junction boxes, the kit comprising:
a plurality of first mounting tubes having a first length;
a plurality of second mounting tubes having a second length that is larger than said first length;
a plurality of third mounting tubes having a third length that is larger than said first length and said second length;
wherein each of said plurality of first, second and third mounting tubes is a cylindrical, substantially non-compressible tube having an inner diameter of between 0.125 inch and 0.175 inch, and
wherein each of said plurality of first, second and third mounting tubes is formed of conductive material, thereby providing rigidity and allowing for continuance of grounding between an electrical device and a junction box to which the electrical device is to be mounted.

10. The kit of claim 9, wherein said mounting tubes have an outer diameter of approximately ¼ inch.

11. The kit of claim 9, wherein said mounting tubes have a length selected from the group consisting of: ¼ inch, ⅜ inch, ½ inch, ⅝ inch, ¾ inch, ⅞ inch, 1 inch, 1¼ inch, and 2 inches.

12. The kit of claim 9, wherein each of said mounting tubes is greater than ¼ inch.

13. The kit of claim 9, wherein each of said mounting tubes is completely hollow without any internal projections.

14. The kit of claim 9, further comprising a carrying case with compartments sized to receive the plurality of first mounting tubes, the plurality of second mounting tubes, and the plurality of third mounting tubes, respectively.

15. The kit of claim 9, further comprising a plurality of first mounting screws having a size corresponding to the plurality of first mounting tubes, a plurality of second mounting screws having a size corresponding to the plurality of second mounting tubes, and a plurality of third mounting screws having a size corresponding to the plurality of third mounting tubes.

16. A method of mounting an electrical device to a junction box, the method comprising:
determining a first gap distance between a first mounting sleeve of a junction box for receiving a first screw and a first location on a plane of an exterior mounting surface to which an electrical device is to be mounted;
selecting a first mounting tube having a length equal or substantially equal to the first determined gap distance from a kit of mounting tubes having a plurality of lengths varying from ¼ inch to 2 inches;
determining a second gap distance between a second mounting sleeve of a junction box for receiving a second screw and a second location on a plane of an exterior mounting surface to which an electrical device is to be mounted;
selecting a second mounting tube having a length equal or substantially equal to the second determined gap distance from said kit of mounting tubes;
inserting the first screw within the first mounting tube;
inserting a distal end of the first screw through a slot of a mounting member of the electrical device;
inserting the distal end of the first screw through an opening of the first mounting sleeve and rotating the screw until the first mounting tube substantially hinders further rotation;
inserting the second screw within the second mounting tube;
inserting a distal end of the second screw through a second slot of the mounting member of the electrical device;
inserting the distal end of the second screw through an opening of the second mounting sleeve and rotating the screw until the second mounting tube substantially hinders further rotation;
wherein the first mounting tube and the second mounting tube comprise substantially non-compressible metallic tubes; and
wherein the first mounting tube and/or the second mounting tube are configured to provide continuous ground conductivity from the electrical device to the junction box.

17. The method of claim 16, wherein the first mounting tube and the second mounting tube have the same length.

18. The method of claim 16, wherein the first mounting tube and the second mounting tube have different lengths.

19. The method of claim 16, wherein the first gap distance and the second gap distance include a width of an exterior wall surface treatment.

20. The method of claim 16, further comprising adjusting a length of the first and/or second mounting tubes based on the measured gap distances.
